(19) United States
(12) Patent Application Publication
(10) Pub. No.: US 2020/0090953 A1
(43) Pub. Date: Mar. 19, 2020

(54) METHOD OF MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hisashi Onodera, Oshu Iwate (JP); Hiroki Inoue, Kitakami Iwate (JP)

(21) Appl. No.: 16/269,960

(22) Filed: Feb. 7, 2019

(30) Foreign Application Priority Data
Sep. 19, 2018 (JP) 2018-175443

(51) Int. Cl. H01L 21/56; H01L 23/00

(52) U.S. Cl. CPC H01L 21/56; H01L 2224/8392; H01L 24/83

(57) ABSTRACT

A method of manufacturing a semiconductor device according to an embodiment includes forming a bonding layer containing a metal on a first surface of a first semiconductor substrate having the first surface and a first back surface; bonding the first semiconductor substrate and a second semiconductor substrate having a second surface and a second back surface so that the second surface is in contact with the bonding layer; and forming a coating layer covering the bonding layer on an outer peripheral portion of the second semiconductor substrate.

### CROSS-REFERENCE TO RELATED APPLICATION

This application is based upon and claims the benefit of priority from Japanese Patent Application No. 2018-175443, filed on Sep. 19, 2018, the entire contents of which are incorporated herein by reference.

### FIELD

Embodiments described herein relate generally to a method of manufacturing a semiconductor device.

### BACKGROUND

There is a technique of bonding two semiconductor substrates with a bonding layer containing a metal interposed therebetween. It is desired to prevent metal contamination originated from a bonding layer containing a metal when processing the bonded semiconductor substrates.

### BRIEF DESCRIPTION OF THE DRAWINGS

FIG. 1 is a schematic diagram of a method of manufacturing a semiconductor device according to an embodiment;

FIG. 2 is a schematic diagram of the method of manufacturing a semiconductor device according to the embodiment; and

FIG. 3 is a schematic diagram of the method of manufacturing a semiconductor device according to the embodiment.

### DETAILED DESCRIPTION

In this specification, the same or similar members are denoted by the same reference numerals, and in some cases, redundant description thereof may be omitted.

In this specification, in order to indicate the positional relationship of parts or the like, in some cases, the upward direction of the drawing may be described as “upper”, and the downward direction of the drawing may be described as “lower”. In this specification, the concepts of “upper” and “lower” are not necessarily terms indicating the relationship with the direction of gravity.

A method of manufacturing a semiconductor device according to an embodiment includes: forming a bonding layer containing a metal on a first surface of a first semiconductor substrate having the first surface and a first back surface; bonding the first semiconductor substrate and a second semiconductor substrate having a second surface and a second back surface so that the second surface is in contact with the bonding layer; and forming a coating layer covering the bonding layer on an outer peripheral portion of the second semiconductor substrate.

In the method of manufacturing a semiconductor device according to the embodiment, two semiconductor substrates are bonded to each other with a bonding layer containing a metal interposed therebetween, and the bonded semiconductor substrates are processed.

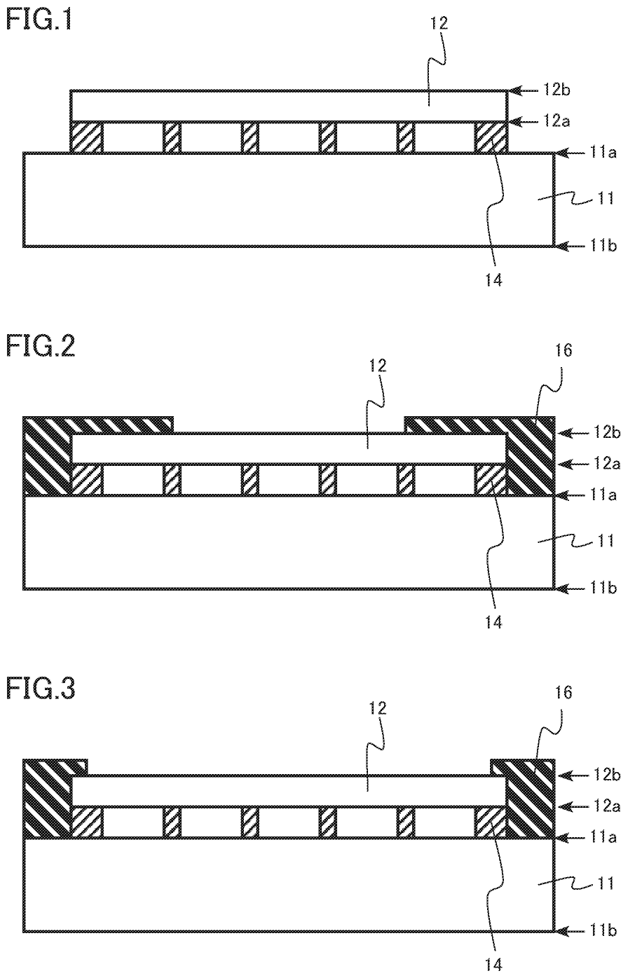

FIG. 1, FIG. 2, and FIG. 3 are schematic cross-sectional views of the method of manufacturing a semiconductor device according to the embodiment.

First, a first silicon wafer 11 (first semiconductor substrate) and a second silicon wafer 12 (second semiconductor substrate) are prepared.

The first silicon wafer 11 has a first surface 11a and a first back surface 11b. For example, a semiconductor element (not illustrated) is formed on the side of the first surface 11a of the first silicon wafer 11.

The second silicon wafer 12 has a second surface 12a and a second back surface 12b. For example, a semiconductor element (not illustrated) is formed on the side of the second surface 12a of the second silicon wafer 12.

Next, a bonding layer 14 containing a metal is formed on the first surface 11a of the first silicon wafer 11. The bonding layer 14 is not formed on the outer peripheral portion of the first silicon wafer 11.

The bonding layer 14 is, for example, a eutectic alloy.

Next, the first silicon wafer 11 and the second silicon wafer 12 are bonded so that the second surface 12a of the second silicon wafer 12 is in contact with the bonding layer 14 (FIG. 1).

Next, a solder resist (coating material) for covering the side surface of the bonding layer 14 is applied to the region including the outer peripheral portion of the second silicon wafer 12. The solder resist is dropped from a nozzle onto the outer peripheral portion of the second silicon wafer 12 by using a known coating apparatus. By doing so, a solder resist layer 16 is formed (FIG. 2).

The solder resist layer 16 is an example of a coating layer. The solder resist of the embodiment is a negative type photosensitive resin.

Next, a portion of the solder resist layer 16 on the second back surface 12b is exposed to light by using a known exposure apparatus, and a development process is performed. The solder resist layer 16 other than the exposed portion is removed by a development process. The solder resist layer 16 of the center portion is removed while the solder resist layer 16 of the outer peripheral portion of the second silicon wafer 12 remains (FIG. 3). After that, heat treatment for curing the solder resist layer 16 is performed.

In addition, herein, the outer peripheral portion of the second silicon wafer 12 includes at least the outer peripheral side surface of the second silicon wafer and the side surface of the bonding layer 14 in the vicinity of the outer peripheral side surface.

The solder resist layer 16 is in contact with the first surface 11a of the first silicon wafer 11 and the second back surface 12b of the second silicon wafer 12. The solder resist layer 16 prevents metal contamination originated from the bonding layer 14 from occurring in the subsequent manufacturing process. In addition, in the subsequent manufacturing process, it is prevented that the bonding layer 14 is unintentionally and greatly etched.

Next, the function and effect of the method of manufacturing a semiconductor device according to the embodiment will be described.

There is a technique of bonding two semiconductor substrates with a bonding layer containing a metal interposed therebetween. It is preferable to prevent metal contamination originated from the bonding layer containing a metal when processing a bonded semiconductor substrate.

In the method of manufacturing a semiconductor device according to the embodiment, a manufacturing process subsequent to the bonding of the first silicon wafer 11 and the second silicon wafer 12 with the bonding layer 14 containing a metal is, for example, a process of forming the wiring on the second back surface 12b of the second silicon wafer 12. Before the formation of the wiring, the solder resist layer 16 covering the bonding layer 14 is provided on the outer peripheral portions of the second silicon wafer 12 and the first silicon wafer 11. The formation of the wiring is performed in a state where the solder resist layer 16 to be the coating layer covers the bonding layer 14.

If the solder resist layer 16 does not cover the bonding layer 14, for example, after patterning the metal film to be the wiring, when the resist pattern is removed by wet etching, the bonding layer 14 is exposed to the wet etching solution. For this reason, metal contamination originated from the bonding layer 14 may occur. In addition, there is a concern that the bonding layer 14 may be unintentionally and greatly etched.

In addition, if the solder resist layer 16 does not cover the bonding layer 14, for example, when the underlying layer of the metal film to be the wiring is removed by wet etching, the bonding layer 14 is exposed to the wet etching solution. Therefore, there is a concern that metal contamination originated from the bonding layer 14 may occur. In addition, the bonding layer 14 may be unintentionally and greatly etched.

According to the method of manufacturing a semiconductor device of the embodiment, the solder resist layer 16 is provided, so that the bonding layer 14 is prevented from being exposed to the wet etching solution. Therefore, it is possible to realize the method of manufacturing a semiconductor device capable of preventing metal contamination originated from the bonding layer 14. As a result, it is possible to realize a semiconductor device having high yield and high reliability.

In the embodiment, the case where the coating layer contains a solder resist has been described as an example, but the coating layer is not limited to the solder resist, and, for example, other resins such as photosensitive polyimide or non-photosensitive polyimide may be used. In addition, the coating layer is not necessarily limited to a resin, but the coating layer may be an inorganic insulator such as an oxide film, a nitride film, or an oxynitride film.

While certain embodiments have been described, these embodiments have been presented by way of example only, and are not intended to limit the scope of the inventions. Indeed, the method of manufacturing a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a bonding layer containing a metal on a first surface of a first semiconductor substrate having the first surface and a first back surface;
bonding the first semiconductor substrate and a second semiconductor substrate having a second surface and a second back surface so that the second surface is in contact with the bonding layer; and
forming a coating layer covering the bonding layer on an outer peripheral portion of the second semiconductor substrate.

2. The method of manufacturing a semiconductor device according to claim 1, wherein the coating layer contains a resin.

3. The method of manufacturing a semiconductor device according to claim 2, wherein the resin is a photosensitive resin.

4. The method of manufacturing a semiconductor device according to claim 1, wherein the coating layer is in contact with the first surface and the second back surface.

5. The method of manufacturing a semiconductor device according to claim 2, wherein the coating layer is in contact with the first surface and the second back surface.

6. The method of manufacturing a semiconductor device according to claim 3, wherein the coating layer is in contact with the first surface and the second back surface.

7. The method of manufacturing a semiconductor device according to claim 1, wherein, in the formation of the coating layer, a coating material is dropped onto a region including the outer peripheral portion of the second semiconductor substrate, the coating material on the second back surface is removed while the coating material on the outer peripheral portion of the second semiconductor substrate remains, and the coating material is subjected to heat treatment.

8. The method of manufacturing a semiconductor device according to claim 7, wherein the coating material is a solder resist.

9. The method of manufacturing a semiconductor device according to claim 1, wherein a wiring is formed on the second back surface after forming the coating layer.

10. The method of manufacturing a semiconductor device according to claim 9, wherein wet etching is performed after forming the coating layer.

11. The method of manufacturing a semiconductor device according to claim 1, wherein the first semiconductor substrate and the second semiconductor substrate are silicon wafers.
